(19) United States
(12) Patent Application Publication
(10) Pub. No.: US 2010/0187698 A1
(43) Pub. Date: Jul. 29, 2010

(54) SEMICONDUCTOR DEVICE AND METHOD FOR MANUFACTURING THE SAME

(75) Inventor: Hiroyuki UCHIYAMA, Tokyo (JP)

Correspondence Address: YOUNG & THOMPSON, 209 Madison Street, Suite 500, Alexandria, VA, 22314, US

(73) Assignee: ELPIDA MEMORY, INC, Tokyo (JP)

(21) Appl. No.: 12/694,707

(22) Filed: Jan. 27, 2010

(30) Foreign Application Priority Data
Jan. 27, 2009 (JP) 2009-015657

(51) Int. Cl. H01L 23/522; H01L 23/48

(52) U.S. Cl. 257/774; 257/776; 257/E23.142; 257/E23.011

(57) ABSTRACT

A semiconductor device includes a first wiring layer, a first interlayer insulating film over the first wiring layer, a second wiring layer crossing the first wiring layer and provided on the first interlayer insulating film, a second interlayer insulating film over the second wiring layer, and a via conductor electrically connecting the first wiring layer and the second wiring layer together. The second wiring layer includes a space separating the second wiring layer into pieces, the space being located at a position where the second wiring layer crosses the first wiring layer. The via conductor passes through the separation space such that the separated pieces of the second wiring layer are electrically connected together, the via conductor extending to the first wiring layer through the second interlayer insulating film and the first interlayer insulating film.

### BACKGROUND OF THE INVENTION

1. Field of the Invention

The present invention relates to a semiconductor device and a method for manufacturing the semiconductor device, and in particular, to a semiconductor device with a multilayer wiring structure and a method for manufacturing the semiconductor device.

2. Description of Related Art

In order to improve the integration degree of logic ICs (Integrated Circuits), a multilayer wiring structure has been adopted in which a plurality of wires are stacked in the direction of the thickness of the wires via interlayer insulating films. In this multilayer wiring structure, the upper layer-side wire and the lower layer-side wire are connected together by via conductors filled in through holes formed in the corresponding interlayer insulating films.

Japanese Patent Laid-Open No. 9-27589 describes a multilayer wiring structure formed as follows in order to reduce a wiring pitch. The second layer wire following the first layer wire and an even number-th wire located above the second layer wire extend in an X direction or a Y direction. The third layer wire and an odd number-th wire located above the third layer wire extend in the Y or X direction so as to cross the second wire. Moreover, the wiring pitch of the even number-th wire is the same as that of the second layer wire. The wiring pitch of the odd number-th wire is the same as that of the third layer wire.

The multilayer wiring structure is further formed as follows in order to increase the degree of freedom of the layout of through-holes. An mth (m is an even number) wire located above the second layer wire is displaced from an (m−2)th layer wire located below the mth wire, by a distance equal to half of the winding pitch of the second layer wire. Furthermore, an nth (n is an odd number) wire located above the third layer wire is displaced from an (n−2)th layer wire located below the nth wire, by a distance equal to half of the winding pitch of the third layer wire.

### SUMMARY

In the conventional manufacture of a semiconductor device with a multilayer wiring structure, the through-holes connecting the wiring layers together are formed every time a wiring layer is formed. That is, formation of five wiring layers requires four through-hole forming processes. This makes difficult a cost reduction based on simplification of the process of forming a multilayer wiring structure.

Furthermore, the via conductors in the through-holes connect the two wiring layers laid on top of each other. Thus, in a multilayer wiring structure including at least three wiring layers, to allow an upper wire and a lower wire to be connected together without being connected to an intermediate wiring layer, a conductive layer (island pattern) electrically separated from the intermediate wiring layer needs to be formed, only for connection to the via conductors, on an interlayer insulating film on which the intermediate wiring layer is formed. Thus, the intermediate wiring layer needs to be located so as to circumvent the island pattern, disadvantageously reducing in a reduced wiring area efficiency.

In one embodiment, there is provided a semiconductor device including:

a base insulating film on a semiconductor substrate;

a first wiring layer on the base insulating film;

a first interlayer insulating film over the first wiring layer;

a second wiring layer crossing the first wiring layer and provided on the first interlayer insulating film;

a second interlayer insulating film over the second wiring layer; and

a via conductor electrically connecting the first wiring layer and the second wiring layer together,

wherein the second wiring layer includes a separation space separating the second wiring layer into pieces, the separation space being located at a position where the second wiring layer crosses the first wiring layer, and

the via conductor passes through the separation space such that the separated pieces of the second wiring layer are electrically connected together, the via conductor extending to the first wiring layer through the second interlayer insulating film and the first interlayer insulating film.

In another embodiment, there is provided the semiconductor device further including:

a third wiring layer provided on the second interlayer insulating film and extending in a substrate plane direction without overlapping the separation space of the second wiring layer; and

a third interlayer insulating film over the third wiring layer,

wherein the third wiring layer includes a protruding portion projecting toward the separation space-side of the second wiring layer, and

the via conductor extends through the third interlayer insulating film and contacts the protruding portion, whereby the third wiring layer is electrically connected to the first wiring layer and the second wiring layer.

In another embodiment, there is provided the semiconductor device wherein the semiconductor device including a multilayer wiring structure provided on a semiconductor substrate, the multilayer wiring structure including a plurality of wiring layers and interlayer insulating films each provided between the wiring layers;

the multilayer wiring structure includes:
the nth wiring layers (n is an odd number) from the lower layer side extending in a first direction, the nth wiring layers being arranged at a first pitch or a pitch equal to an integral multiple of the first pitch,
the mth wiring layers (m is an even number) from the lower layer side extending in a second direction crossing the first direction, the mth wiring layers being arranged at a second pitch or a pitch equal to an integral multiple of the second pitch, and

a via conductor electrically connecting one of the nth wiring layers to one of the mth wiring layers;

the (n+2)th wiring layers from the lower layer side are displaced from the nth wiring layers by a distance half of the first pitch;

the (m+2)th wiring layers from the lower layer side are displaced from the mth wiring layers by a distance half of the second pitch;

the upper layer-side wiring layer, as the second wiring layer, connected to the via conductor includes a separation space separating the upper layer-side wiring layer into pieces, the separation space being located at a position where the upper layer-side wiring layer crosses the lower layer-side wiring layer, as the first wiring layer, connected to the via conductor; and

the via conductor extends from above the upper layer-side wiring layer to the lower layer-side wiring layer through the separation space such that the separated pieces of the upper layer-side wiring layer are electrically connected together, the via conductor extending through between other wiring layers.

In another embodiment, there is provided the semiconductor device wherein another wiring layer located above the upper layer-side wiring layer or another wiring layer located between the lower layer-side wiring layer and the upper layer-side wiring layer includes a protruding portion projecting toward the separation space side of the upper wiring layer, and

the via conductor contacts the protruding portion, whereby the other wiring layer is electrically connected to the upper layer-side wiring layer and the lower layer-side wiring layer.

According to an embodiment, it is possible to provide a semiconductor device including a multilayer wiring structure that can be manufactured by a simple process. According to another embodiment, it is possible to provide a semiconductor device which can be manufactured by a simple process and which has an improved wiring area efficiency.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing the layout of wiring according to an embodiment of the present invention;

FIG. 2 is a sectional view taken along line A-A′ in FIG. 1;

FIG. 3 is a sectional view taken along line B-B′ in FIG. 1;

FIG. 4 is a sectional view taken along line C-C′ in FIG. 1;

FIG. 5 is a sectional view taken along line D-D′ in FIG. 1; and

FIG. 6 is a sectional view taken along line E-E′ in FIG. 1.

### DETAILED DESCRIPTION OF THE PREFERRED EMBODIMENTS

A semiconductor device according to an embodiment of the present invention includes a base insulating film on a semiconductor substrate, a first wiring layer on the base insulating film, a first interlayer insulating film over the first wiring layer, a second wiring layer crossing the first wiring layer and provided on the first interlayer insulating film, a second interlayer insulating film over the second wiring layer, and a via conductor electrically connecting the first wiring layer and the second wiring layer together.

The second wiring layer is separated into two pieces at a position where the second wiring layer crosses the first wiring layer. A space is thus created between an end of one of the resulting pieces of the second wiring layer and an end of the other piece. The via conductor is provided at the crossing position so as to fill the separation space. The via conductor thus electrically connects the above-described ends together. The via conductor extends to a lower layer-side wiring layer through the second interlayer insulating film and the first interlayer insulating film via the separation space.

According to this structure, the via conductor in the one through-hole enables the lower layer-side wiring layer (first wiring layer) to be electrically connected to the upper layer-side wiring layer (second wiring layer) and also enables a further upper layer-side conductive portion to be electrically connected to the lower and upper layer-side wiring layers. Thus, the process of forming the via conductor can be simplified, enabling a reduction in manufacturing costs.

Furthermore, in the above-described structure, a third wiring layer may be provided on the second interlayer insulating film and extend in a substrate plane direction without overlapping the separation space of the second wiring layer. A third interlayer insulating film may also be provided over the third wiring layer. The third wiring layer may include a protruding portion projecting toward the separation space side of the second wiring layer. The via conductor may penetrate the third interlayer insulating film and contact the protruding portion, and thus the third wiring layer can be electrically connected to the first wiring layer and the second wiring layer. The third wiring layer may extend in the substrate plane direction without overlapping the first wiring layer or the second wiring layer, and may be located adjacent and parallel to the first wiring layer or the second wiring layer.

According to this structure, the via conductor in the one through-hole enables the electric connection between the lower layer-side wiring layer (first wiring layer) and the upper layer-side wiring layer (second wiring layer) and the further upper layer-side wiring layer (third wiring layer). The via conductor further enables these wiring layers to be connected a further upper layer-side conductive portion. Thus, the process of forming the via conductor can be simplified, enabling a reduction in manufacturing costs.

Furthermore, in the above-described structure, the first wiring layer may include a wide portion with a width extending in a direction perpendicular to an extending direction of the first wiring layer, the width being larger than the size of the first wiring layer-side connection end of the via conductor in the same direction. The via conductor may be connected to the inside of the wide portion.

According to this structure, the first wiring layer and the via conductor can be easily connected together.

The above-described connection structures for the wiring layers correspond to examples of the connection between two layers and the connection between three layers. However, similar structures may be used to connect more than three wiring layers together.

For example, the following structure can be formed. A fourth wiring layer is provided on the third interlayer insulating film and crosses the first wiring layer or the second wiring layer at the position where the first wiring layer crosses the second wiring layer. A fourth interlayer insulating film is provided over the fourth wiring layer. The fourth wiring layer is separated into two pieces at the position where the fourth wiring layer crosses the first wiring layer or the second wiring layer. A space is thus created between an end of one of the resulting pieces of the fourth wiring layer and an end of the other piece. The via conductor connecting the first wiring layer, the second wiring layer, and the third wiring layer together is provided so as to fill the separation space, and thus the via conductor electrically connects the above-described ends together. According to this structure, the via conductor in the one through-hole enables the first to fourth wiring layers to be electrically connected together. The fourth wiring layer may be formed without the need to provide the third wiring layer and the third interlayer insulating film. In this case, the via conductor in the one through-hole electrically connects the first, second, and fourth wiring layers together.

Moreover, the following structure may be formed. A fifth wiring layer extending in a substrate plane direction without overlapping the separation space is provided on the fourth interlayer insulating film. A fifth interlayer insulating film is provided over the fifth wiring layer. The fifth wiring layer includes a protruding portion projecting toward the separation space side. The via conductor penetrates the fifth interlayer insulating film and contacts the protruding portion. According to this structure, the via conductor in the one through-hole enables the first to fifth wiring layers to be electrically connected together.

The above-described connection structures for the wiring layers is applicable to a multilayer wiring structure including wiring layers extending in a first direction, wiring layers extending in a second direction crossing the first direction, and interlayer insulating films each provided between the wiring layers.

In this multilayer wiring structure, the wiring layers extending in the first direction and arranged adjacent to each other in a substrate plane direction are arranged at a first pitch or a pitch equal to an integral multiple of the first pitch; the wiring layers extending in the second direction and arranged adjacent to each other in a substrate plane direction are arranged at a second pitch or a pitch equal to an integral multiple of the second pitch; the wiring layers extending in the first direction which are arranged adjacent to each other in the interlayer direction (the direction perpendicular to the substrate plane) across the wiring layer extending in the second direction are displaced, by a distance equal to half of the first pitch, from each other; and the wiring layers extending in the second direction which are arranged adjacent to each other in the interlayer direction (the direction perpendicular to the substrate plane) across the wiring layer extending in the first direction are displaced, by a distance equal to half of the second pitch, from each other. For a sufficient inter-wiring space in a substrate plane direction, the first direction and the second direction desirably cross perpendicularly.

In this multilayer wiring structure, the above-described via conductor is provided so as to electrically connect the upper layer-side wiring layer and the lower layer-side wiring layer together and to extend from above the upper layer-side wiring layer to the lower layer-side wiring layer through between other wiring layers. The via conductor may extend from the upper layer-side wiring layer to the lower layer-side wiring layer through between other wiring layers. Also, the via conductor may extend from above the upper layer-side wiring layer to the upper layer-side wiring layer through between other wiring layers and then to the lower layer-side wiring layer without passing through between other wiring layers. Here, the lower layer-side wiring layer corresponds to the first wiring layer. The upper layer-side wiring layer corresponds to the second wiring layer.

In this multilayer wiring structure, wiring layers extending in the same direction and arranged adjacent to each other in the interlayer direction across a wiring layer extending in the different direction are displaced from each other without overlapping. Thus, the via conductor connected to a wiring layer can be extended further upward without contacting any other wiring layers located above the wiring layer. This eliminates the need for the above-described island pattern serving only to connect an upper layer-side via conductor to a lower layer-side via conductor. As a result, wiring area efficiency can be improved. Furthermore, the via conductor in the one through-hole enables the upper and lower wiring layers to be connected together. Therefore, the process of forming the via conductor can be simplified, enabling a reduction in manufacturing costs.

An embodiment of the present invention will specifically be described below with reference to the drawings.

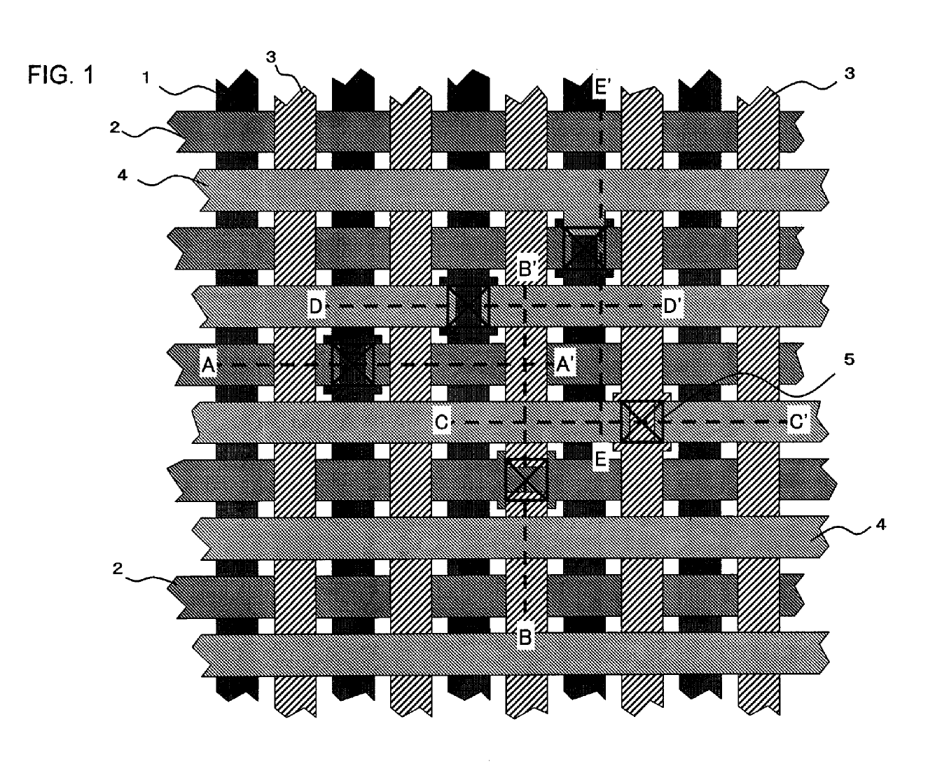

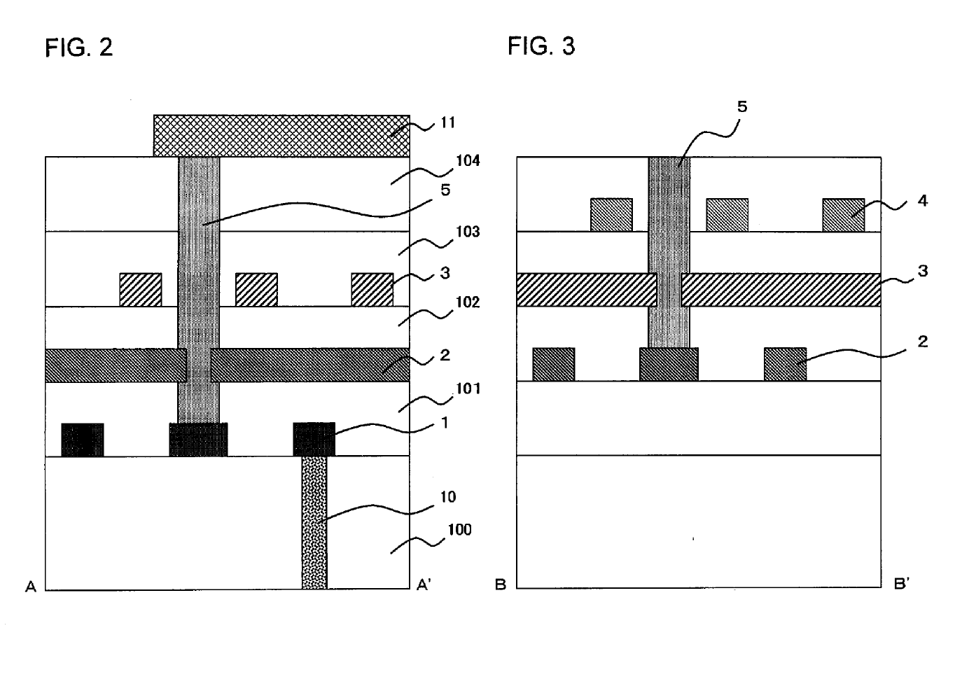

FIG. 1 shows an example of the layout of a four-layer wiring structure including first wiring layers 1, second wiring layers 2, third wiring layers 3, and fourth wiring layers 4. FIGS. 2 to 6 are sectional views corresponding to cutting lines in FIG. 1. As shown in the sectional views, the wiring layers 1 to 4 and interlayer insulating films 101 to 104 are alternately stacked on a base insulating film 100.

As shown in FIG. 1, the first, second, third and fourth wiring layers 1 to 4 are each arranged at the same pitch. The wiring layers 1 are orthogonal to the wiring layers 2. The wiring layers 2 are orthogonal to the wiring layers 3. The wiring layers 3 are orthogonal to the wiring layers 4. Furthermore, the pitch of the wiring layers 1 is shifted from the pitch of the wiring layers 3 by a distance equal to half the pitch. The pitch of the wiring layers 2 is shifted from the pitch of the wiring layers 4 by a distance equal to half the pitch. Here, for description, the figure shows only the wiring portion in which the wiring layers are arranged at the same pitch. However, each of the wiring layers may include wider wiring layers arranged at a pitch that is an integral multiple of the above-described wiring pitch. A certain wiring layer may be removed with the wiring layers each arranged opposite the removed wiring layer remaining intact, thus increasing the wiring space.

Connection plug 5 in a through-hole configured to connect the wiring layers is arranged at a position where the wiring layers cross each other. The connection plug thus enables any number of wiring layers 1 to 4 to be freely connected together.

For example, a plug (arranged on line A-A′) connecting a lower layer-side wiring layer (one of wiring layers 1) and an upper layer-side wiring layer (one of wiring layers 2) together is arranged at the position where the wiring layers cross each other. Moreover, the plug is arranged in the space between the wiring layers 3 and the space between the wiring layers 4 without contacting the wiring layers 3 and 4. The upper layer-side wiring layer (wiring layer 2) is separated into two pieces at the region where the plug is located. Thus, between the pieces of the upper layer-side wiring layer, a space is created which is smaller than the diameter of the through-hole by a dimension corresponding to an alignment margin. The lower layer-side wiring layer (wiring layer 1) includes a dog bone shape portion located at the region where the plug is placed. The dog bone shape portion is set to be wider than the remaining part of the wiring layer 1 by the dimension corresponding to the alignment margin, so as to accommodate the through-hole.

FIG. 2 shows a sectional structure seen along line A-A′. The through-hole is opened from above the wiring layers 4. The plug 5 in the through-hole extends to the lower layer-side wiring layer (wiring layer 1) through the space between the wiring layers 4, the space between the wiring layers 3, and the space separating the upper layer-side wiring layer (wiring layer 2) into the two pieces. As a result, the lower layer-side wiring layer (wiring layer 1) and the upper layer-side wiring layer (wiring layer 2) are electrically connected together. The plug contacts the upper layer-side wiring layer (wiring layer 2) but not the wiring layers 3 and 4. Thus, in the structure in the present example, the plug enables the upper and lower wiring layers to be connected together and can be extended upward without contacting the other wiring layers. This allows the wiring area efficiency to be improved. Although not shown in FIG. 1, the following may be formed as required: the plug 10 (for example, a contact plug) for connection to a conductive portion (for example, an element such as a MOS device) located below the multilayer wiring structure or a wire 11 located above the multilayer wiring structure.

A plug (arranged on line B-B′) connecting a lower layer-side wiring layer (one of wiring layers 2) and an upper layer-side wiring layer (one of wirings 3) together is arranged at the position where the wiring layers cross each other. Moreover, the plug is arranged in the space between the wiring layers 4 without contacting the wiring layers 4. The upper layer-side wiring layer (wiring layer 3) is separated into two pieces at the region where the plug is located. Thus, between the pieces of the upper layer-side wiring layer, a space is created which is smaller than the diameter of the through-hole by the dimension corresponding to the alignment margin. The lower layer-side wiring layer (wiring layer 2) includes a dog bone shape portion located at the region where the plug is placed. The dog bone shape portion is set to be wider than the remaining part of the wiring layer 2 by the dimension corresponding to the alignment margin, so as to accommodate the through-hole.

FIG. 3 shows a sectional structure seen along line B-B′. The through-hole is opened from above the wiring layers 4. The plug 5 in the through-hole extends to the lower layer-side wiring layer (wiring layer 2) through the space between the wiring layers 4 and the space separating the upper layer-side wiring layer (wiring layer 3) into two pieces. As a result, the lower layer-side wiring layer (wiring layer 2) and the upper layer-side wiring layer (wiring layer 3) are electrically connected together. The plug contacts the upper layer-side wiring layer (wiring layer 3) but not the wiring layers 4. Thus, in the structure in the present example, the plug enables the upper and lower wiring layers to be connected together and can be extended upward without contacting the other wiring layers. This allows the wiring area efficiency to be improved. Furthermore, when a through-hole is formed by highly selective etching, the etching stops at the dog bone shape portion of the wiring layer 2. This prevents the plug from reaching the wiring layer 1.

A plug (arranged on line C-C′) connecting a lower layer-side wiring layer (one of wiring layers 3) and an upper layer-side wiring layer (one of wiring layers 4) together is arranged at the position where the wiring layers cross each other. The upper layer-side wiring (wiring layer 4) is separated into two pieces at the region where the plug is located. Thus, between the pieces of the upper layer-side wiring layer, a space is created which is smaller than the diameter of the through-hole by the dimension corresponding to the alignment margin. The lower layer-side wiring layer (wiring layer 3) includes a dog bone shape portion located at the region where the plug is placed. The dog bone shape portion is set to be wider than the remaining part of the wiring layer 3 by the dimension corresponding to the alignment margin, so as to accommodate the through-hole.

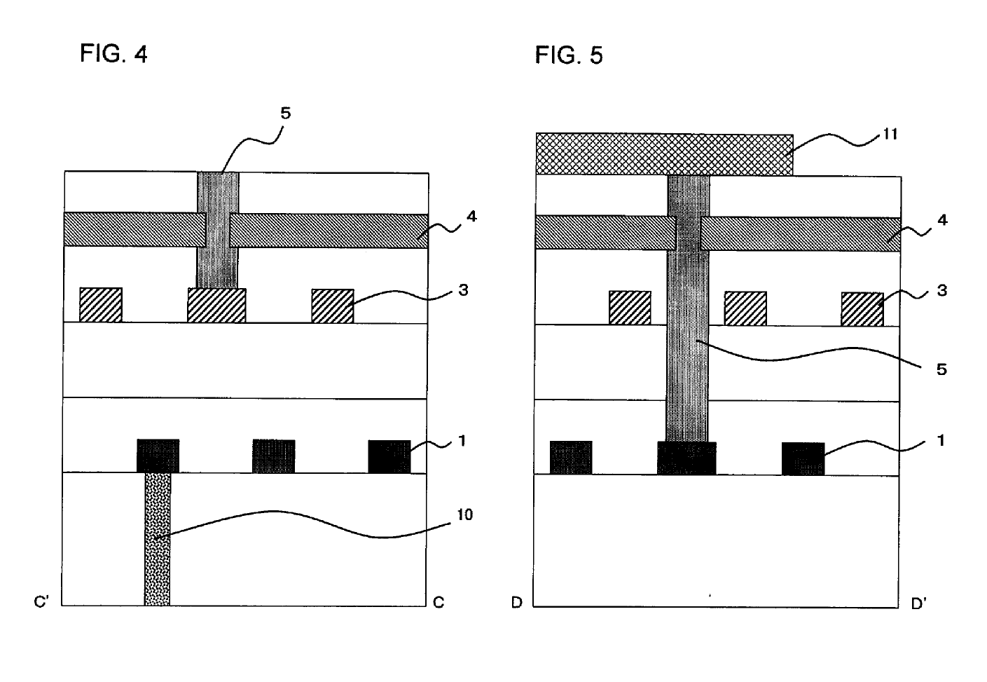

FIG. 4 shows a sectional structure seen along line C-C′. The through-hole is opened from above the wiring layers 4. The plug 5 in the through-hole extends to the lower layer-side wiring layer (wiring layer 3) through the space separating the upper layer-side wiring layer (wiring layer 4) into two pieces. As a result, the lower layer-side wiring layer (wiring layer 3) and the upper layer-side wiring layer (wiring layer 4) are electrically connected together. According to the structure in the present example, the plug enables the upper and lower wiring layers to be connected together and can be extended further upward. Furthermore, when a through-hole is formed by highly selective etching, the etching stops at the dog bone shape portion of the wiring layer 3. This prevents the plug from reaching the wiring layers 1 and 2. Although not shown in FIG. 1, the following may be formed as required: the plug 10 (for example, a contact plug) for connection to a conductive portion (for example, an element such as a MOS device) located below the multilayer wiring structure.

A plug (arranged on line D-D′) connecting a lower layer-side wiring layer (one of wiring layers 1) and an upper layer-side wiring layer (one of wiring layers 4) together is arranged at the position where the wiring layers cross each other. Moreover, the plug is arranged in the space between the wiring layers 2 and the space between the wiring layers 3 without contacting the wiring layers 2 and 3. The upper layer-side wiring layer (wiring layer 4) is separated into two pieces at the region where the plug is located. Thus, between the pieces of the upper layer-side wiring layer, a space is created which is smaller than the diameter of the through-hole by the dimension corresponding to the alignment margin. The lower layer-side wiring layer (wiring layer 1) includes a dog bone shape portion located at the region where the plug is placed. The dog bone shape portion is set to be wider than the remaining part of the wiring layer 1 by the dimension corresponding to the alignment margin, so as to accommodate the through-hole.

FIG. 5 shows a sectional structure seen along line D-D′. The through-hole is opened from above the wiring layers 4. The plug 5 in the through-hole extends to the lower layer-side wiring layer (wiring layer 1) through the space separating the upper layer-side wiring layer (wiring layer 4), the space between the wiring layers 3, and the space between the wiring layers 2. As a result, the lower layer-side wiring layer (wiring layer 1) and the upper layer-side wiring layer (wiring layer 4) are electrically connected together. The plug contacts the upper layer-side wiring layer (wiring layer 4) but not the wiring layers 2 and 3. Thus, in the structure in the present example, the plug enables the upper and lower wiring layers to be connected together, without contacting the other wiring layers. This allows the wiring area efficiency to be improved. Furthermore, when a through-hole is formed by highly selective etching, the etching stops at the dog bone shape portion of the lower layer-side wiring layer (wiring layer 1). This prevents the plug from penetrating the base interlayer insulating film 100. Although not shown in FIG. 1, the wire 11 located above the multilayer wiring structure is formed as required.

A plug (arranged on line E-E′) connecting a lower layer-side wiring layer (one of wiring layers 1), an upper layer-side wiring layer (one of wiring layers 2), and an uppermost layer-side wiring layer (one of wiring layers 4) together is located at the position where the lower layer-side wiring layer crosses the upper layer-side wiring layer. Moreover, the plug is located in the space between the wiring layers 3 without contacting the wiring layers 3.

The uppermost layer-side wiring layer (wiring layer 4) includes a protruding portion located at the portion where the wiring layer 4 crosses the lower layer-side wiring layer (wiring layer 1), the protruding portion projecting toward the side of the position where the upper layer-side wiring layer (wiring layer 2) crosses the wiring layer 1. The plug passes through the wiring layer 4 to contact the protruding portion. The protruding portion is located so as to overlap the through-hole by a dimension corresponding to the alignment margin.

The upper layer-side wiring layer (wiring layer 2) with respect to the lower layer-side wiring layer (wiring layer 1) is separated into two pieces at the region where the plug is located. Thus, between the pieces of the upper layer-side wiring layer, a space is created which is smaller than the diameter of the through-hole by the dimension corresponding to the alignment margin. The lower layer-side wiring layer (wiring layer 1) includes a dog bone shape portion located at the region where the plug is placed. The dog bone shape portion is set to be wider than the remaining part of the wiring layer 1 by the dimension corresponding to the alignment margin, so as to accommodate the through-hole.

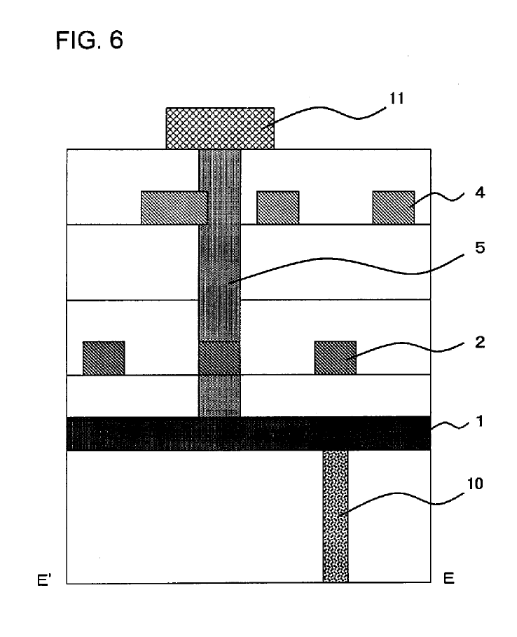

FIG. 6 shows a sectional structure seen along line E-E′. The through-hole is opened from above the wiring layers 4. The plug 5 in the through-hole extends to the lower layer-side wiring layer (wiring layer 1) through the space between the wiring layers 4, the space between the wiring layers 3, and the space separating the upper layer-side wiring layer (wiring layer 2) into two pieces. As a result, the lower layer-side wiring layer (wiring layer 1), the upper layer-side wiring layer (wiring layer 2), and the uppermost layer-side wiring layer (wiring layer 4) are electrically connected together. The plug contacts the protruding portion of the wiring layer 4 and the opposite sides of the space between the pieces of the wiring layer 2 but not the wiring layers 3. Thus, in this wiring structure, at least three wiring layers can be connected together during a single step of forming a through-hole, simplifying the manufacturing process. Furthermore, the wiring area efficiency and the degree of freedom of wire connections can be improved. Additionally, when a through-hole is formed by highly selective etching, the etching stops at the dog bone shape portion of the wiring layer 1. This prevents the plug from penetrating the base interlayer insulating film 100. Although not shown in FIG. 1, the following may be formed as required: the plug 10 (for example, a contact plug) for connection to a conductive portion (for example, an element such as a MOS device) located below the multilayer wiring structure or the wire 11 located above the multilayer wiring structure.

The above-described multilayer wiring structure may be produced as follows.

An element such as a MOS transistor is formed on a semiconductor substrate. Then, an insulating film 100 is formed which corresponds to the base of the multilayer wiring structure. A contact hole reaching the element is formed in the base insulating film. As shown in FIG. 2, a conductor such as tungsten is filled into the contact hole to form a contact plug 10.

Then, according to a normal wiring formation method, wiring layers and interlayer insulating films are alternately formed. Thus, a multilayer wiring structure including the wiring layers 1 to 4 is formed. For example, a trench is formed in an insulating film. A copper film is formed so as to fill the trench. A portion of the copper film located outside the trench is removed by CMP (Chemical Mechanical Polishing). Thus, buried wiring composed of the copper in the trench can be formed (damascene method). In this case, the trench pattern is formed such that the above-described separation space or protruding portion is formed in the upper layer-side wiring layer of the inter connected wiring layers.

Then, a normal lithography technique and a normal dry etching technique are used to form a through-hole extending from an insulating film on the wiring layer 4 to the wiring layer 1. A conductive material such as copper is filled into the through-hole to form a plug 5. A wire 11 is formed as required as shown in FIG. 2. The wire 11 may be formed integrally with the plug by a dual damascene method.

Although not shown in the drawings, if the damascene method or the dual damascene method is used, an etching stop film may be provided as required so as to allow a trench pattern or a through-hole to be formed. Furthermore, a barrier film composed of TiN, Ta, TaN, or the like may be formed in the trench or the through-hole.

In another embodiment, there is provided a method for manufacturing a semiconductor device, including:

forming a first wiring layer on a base insulating film on a substrate;

forming a first interlayer insulating film over the first wiring layer;

forming a second wiring layer crossing the first wiring layer and separated into pieces at a position where the second wiring layer crosses the first wiring layer;

forming a second interlayer insulating film over the second wiring layer;

forming a through-hole extending to the first wiring layer through the second interlayer insulating film and the first interlayer insulating film via the separated portion of the second wiring layer such that both opposite ends of the separated pieces of the second wiring layer are exposed in the through-hole; and

filling the through-hole with a conductor such that the ends are electrically connected together and the first wiring layer and the second wiring layer are electrically connected together.

In another embodiment, there is provided the method for manufacturing the semiconductor device, further including:

forming a third wiring layer located on the second interlayer insulating film and extending in a substrate plane direction without overlapping the separation portion of the second wiring layer, and

forming a third interlayer insulating film over the third wiring layer,

wherein the third wiring layer is patterned so as to include a protruding portion projecting toward the separation portion side of the second wiring layer,

the through-hole extends to the first wiring layer through the third interlayer insulating film, the second interlayer insulating film, and the first interlayer insulating film via the separation portion of the second wiring layer such that the protruding portion is exposed in the through-hole, and

the through-hole is filled with a conductor such that the third wiring layer is electrically connected to the first wiring layer and the second wiring layer.

It is apparent that the present invention is not limited to the above embodiments, but may be modified and changed without departing from the scope and spirit of the invention.

What is claimed is:

1. A semiconductor device comprising:
a base insulating film on a semiconductor substrate;
a first wiring layer on the base insulating film;
a first interlayer insulating film over the first wiring layer;
a second wiring layer crossing the first wiring layer and provided on the first interlayer insulating film;
a second interlayer insulating film over the second wiring layer; and
a via conductor electrically connecting the first wiring layer and the second wiring layer together,
wherein the second wiring layer includes a separation space separating the second wiring layer into pieces, the separation space being located at a position where the second wiring layer crosses the first wiring layer, and
the via conductor passes through the separation space such that the separated pieces of the second wiring layer are electrically connected together, the via conductor extending to the first wiring layer through the second interlayer insulating film and the first interlayer insulating film.

2. The semiconductor device according to claim 1, further comprising:
a third wiring layer provided on the second interlayer insulating film and extending in a substrate plane direction without overlapping the separation space of the second wiring layer; and
a third interlayer insulating film over the third wiring layer,
wherein the third wiring layer includes a protruding portion projecting toward the separation space-side of the second wiring layer, and
the via conductor extends through the third interlayer insulating film and contacts the protruding portion, whereby the third wiring layer is electrically connected to the first wiring layer and the second wiring layer.

3. The semiconductor device according to claim 1, wherein the first wiring layer includes a wider portion with a width extending in a direction perpendicular to an extending direction of the first wiring layer, the width of the wider portion being larger than the size of a first wiring layer-side connection end of the via conductor in the same direction, and
the via conductor is connected to an inside of the wider portion.

4. The semiconductor device according to claim 1, wherein the semiconductor device comprising a multilayer wiring structure provided on the semiconductor substrate, the multilayer wiring structure comprising a plurality of wiring layers and interlayer insulating films each provided between the wiring layers;
the multilayer wiring structure comprises:
the nth wiring layers (n is an odd number) from the lower layer side extending in a first direction, the nth wiring layers being arranged at a first pitch or a pitch equal to an integral multiple of the first pitch,
the mth wiring layers (m is an even number) from the lower layer side extending in a second direction crossing the first direction, the mth wiring layers being arranged at a second pitch or a pitch equal to an integral multiple of the second pitch, and
a via conductor electrically connecting one of the nth wiring layers to one of the mth wiring layers;
the (n+2)th wiring layers from the lower layer side are displaced from the nth wiring layers by a distance half of the first pitch;
the (m+2)th wiring layers from the lower layer side are displaced from the mth wiring layers by a distance half of the second pitch;
the upper layer-side wiring layer, as the second wiring layer, connected to the via conductor includes a separation space separating the upper layer-side wiring layer into pieces, the separation space being located at a position where the upper layer-side wiring layer crosses the lower layer-side wiring layer, as the first wiring layer, connected to the via conductor; and
the via conductor extends from above the upper layer-side wiring layer to the lower layer-side wiring layer through the separation space such that the separated pieces of the upper layer-side wiring layer are electrically connected together, the via conductor extending through between other wiring layers.

5. The semiconductor device according to claim 4, wherein another wiring layer located above the upper layer-side wiring layer or another wiring layer located between the lower layer-side wiring layer and the upper layer-side wiring layer includes a protruding portion projecting toward the separation space side of the upper wiring layer, and
the via conductor contacts the protruding portion, whereby the other wiring layer is electrically connected to the upper layer-side wiring layer and the lower layer-side wiring layer.

6. The semiconductor device according to claim 4, wherein the lower layer-side wiring layer includes a wider portion with a width extending in a direction perpendicular to an extending direction of the lower layer-side wiring layer, the width of the wider portion being larger than the size of a lower layer-side-wiring layer-side connection end of the via conductor in the same direction, and
the via conductor is connected to an inside of the wider portion.
